(19) United States
(12) Patent Application Publication
(10) Pub. No.: US 2011/0315544 A1
(43) Pub. Date: Dec. 29, 2011

(54) ARC EVAPORATOR AND METHOD FOR OPERATING THE EVAPORATOR

(75) Inventors: Josu Goikoetxea Larrinaga, Eibar (Guipuzcoa) (ES); Unai Ruiz De Gopegui Llona, Eibar (Guipuzcoa) (ES); Kepa Garmendia Otaegi, Eibar (Guipuzcoa) (ES); Andoni Delgado Castrillo, Eibar (Guipuzcoa) (ES)

(73) Assignee: FUNDACION TEKNIKER, Eibar (Guipuzcoa) (ES)

(21) Appl. No.: 13/142,164

(22) PCT Filed: Dec. 26, 2008
(86) PCT No.: PCT/ES2008/000805

§ 371 Date: Sep. 13, 2011

(51) Int. Cl. C23C 14/32

(52) U.S. Cl. 204/192.38; 204/298.41

(57) ABSTRACT

The invention relates to an arc evaporator which comprises at least one anode (4), a cathode (3) and a system for generating a magnetic field comprising a first subsystem consisting of a set of permanent magnets (8, 9) which produces a converging magnetic field component and a second subsystem comprising at least one coil (10) and configured to operate in at least a first operating mode in which it generates a second diverging magnetic field component.

### TECHNICAL FIELD OF THE INVENTION

The invention is comprised in the field of arc evaporators and, more specifically, in the field of arc evaporators including a magnetic steering system for the arc.

### BACKGROUND OF THE INVENTION

Arc evaporators are systems or machines intended to evaporate an electrically conductive material, such that said material can move through a chamber (in which a state of vacuum or of very low pressure is normally established) to be deposited on a surface of a part to be coated with the material. In other words, machines of this type are used for coating parts and surfaces.

Arc evaporator machines usually comprise, in addition to the chamber itself, at least one anode and at least one cathode, between which an electric arc is established. This arc (which in a typical case can represent a current of 80 A and be applied under a voltage of 22 V) impinges on a point of the cathode (known as cathode spot) and generates, in correspondence with said point, an evaporation of the material of the cathode. Therefore, the cathode is formed from the material which is to be used for the coating, normally in the form of a plate (for example, in the form of a disc) of said material, and forms what is known as the “evaporation target”. To maintain the arc and/or to facilitate the establishment of the arc, a small amount of gas is usually introduced into the chamber. The arc causes an evaporation of the material in the inner surface of the cathode (i.e., on the surface of the cathode which is in contact with the inside of the chamber) in correspondence with the points in which the arc impinges on the surface. This inner surface can face the part or surface to be coated, so that the material vaporized by the arc is deposited on said part or surface. To prevent an overheating of the cathode, a cooling fluid (for example, water) is frequently applied on the cathode, for example, on the outer surface of the cathode.

The arc (or, in the case of a system with multiple arcs, each arc) impinges at all times on a specific point, in which the evaporation of the cathode occurs. The arc moves on the inner surface of the cathode, causing a wear of said surface in correspondence with the path followed by the arc in its movement. If some type of control is not applied on the movement of the arc, said movement can be random, causing a non-homogeneous wear of the cathode, which can entail a poor exploitation of the material of the cathode, the unit cost of which can be quite high.

This problem may be less serious in the case of small-sized evaporators. For example, in evaporators using circular evaporation targets with a diameter of 60 mm it is usually not necessary to adopt special measures to ensure sufficient homogeneity of the wear. However, for larger-sized evaporators, the problem becomes increasingly more important.

To prevent or reduce the random nature of the movement of the arc, for the purpose of making the wear of the cathode more homogeneous, control or steering systems for the movement of the arc, based on magnetic steering systems for the arc, have been developed. These steering systems establish and modify magnetic fields affecting the movement of the electric arc, whereby it is possible to make the wear due to the evaporation of the cathode more homogeneous. On the other hand, these magnetic steering elements contribute to increasing the reliability of the arc evaporator, since they make it impossible or difficult for the arc to accidentally move to a point that is not part of the evaporation surface.

The material evaporated by the arc is highly ionized, and under those conditions its movement is strongly influenced by the nature of the magnetic fields present which, therefore, also have an important influence on the distribution of the evaporated material, on the energy with which it reaches the parts to be coated and, as a consequence of the latter, on the quality of the coating which is obtained.

There are several publications of patents or patent applications which described different systems of this type.

U.S. Pat. No. 4,673,477 describes a magnetic steering system using a permanent magnet which moves, by mechanical means, in the rear part of the plate to be evaporated, such that the variable magnetic field generated by this permanent magnet steers the electric arc on the cathode. This machine optionally also incorporates a magnetic winding surrounding the plate of the cathode for the purpose of reinforcing or reducing the strength of the magnetic field in a direction perpendicular to the active surface of the cathode and thus improve the steering of the electrode. A problem of this machine is that the magnetic system of mobile permanent magnets is very mechanically complex and therefore expensive to implement and susceptible to breakdowns.

U.S. Pat. No. 4,724,058 relates to a machine with a magnetic steering element incorporating coils placed in the rear part of the cathode plate, which steer the electric arc in a single direction parallel to that followed by the coil. For the purpose of reducing the preferred wear effect in a single path, methods are used which attempt to weaken the steering effect of the magnetic field, such that a random component is superimposed on the latter. Specifically, it has been provided that the magnetic field generated by the coil is connected and disconnected such that most of the time the arc moves on the cathode randomly, such that it is only steered by the magnetic field for a very small part of the time.

U.S. Pat. No. 5,861,088 describes a machine with a magnetic steering element including a permanent magnet located in the center of the target and in its rear face, and a coil surrounding the mentioned permanent magnet, the assembly forming a magnetic field concentrator. The system is complemented with a second coil placed on the outside of the evaporator.

WO-A-02/077318 (corresponding to ES-T-2228830 and EP-A-1382711) discloses an evaporator with an operative powerful magnetic steering element using permanent magnets in an advanced position corresponding to the inside of the chamber, so it is necessary to incorporate means for cooling those magnets when the chamber is used for coatings carried out at a high temperature, for example cutting tools, which require process temperatures in the order of 500° C.

U.S. Pat. No. 5,298,136 describes a magnetic steering element for thick targets in circular evaporators, comprising two coils and a magnetic part with a special configuration which is adapted to the edges of the target to be evaporated, such that the assembly works as a single magnetic element, with two magnetic poles. As in the case of the systems described in U.S. Pat. No. 4,724,058 and other similar ones, a problem with the system described in U.S. Pat. No. 5,298,136 is that the magnetically defined path cannot move over the surface of the evaporation target (or it does so in a very small range), so in order to achieve a wear which is not excessive on that path it is necessary to limit the intensity of the magnetic field to allow the arc to have a certain freedom to move away from the pre-established path.

EP-A-1576641 describes a system which allows defining a path on the evaporation target by means of using two coils with opposite polarities, without using ferromagnetic parts, so it is better designed than some of the aforementioned systems to allow the magnetically defined path to move over the surface of the evaporation target.

All the designs of magnetic steering elements mentioned up until now are based on the existence of a path on the surface of the evaporation target formed by points in which the magnetic field perpendicular to the surface of the evaporation target is canceled out, which is the path which will preferably be followed by the electric arc while moving over the surface of the evaporation target. This technique for magnetically steering the arc is known as the steered arc technique. The speed with which the arc moves over the surface of the evaporation target increases with the intensity of the parallel magnetic field, and the emission of microdroplets thus decreases, microdroplets being the most common and important defects present in the layers deposited by cathodic arc evaporation. It is also possible to design the steered arc technology magnetic steering element such that it allows modifying the path followed by the arc, achieving a greater exploitation of the material to be evaporated.

In addition to the steered arc technology type steering elements such as those described up until now, in which the perpendicular magnetic field is canceled out along a path on the evaporation target, which is the path which is preferably followed by the arc in its movement, there are also evaporators in which a magnetic field which does not have such path is used. In these evaporators the magnetic field is substantially perpendicular to the target in its entire surface. This magnetic field perpendicular to the surface of the evaporation target has the particularity of favoring the transmission of the evaporated material from the surface of the target to the surface of the part to be coated, due to the fact that the ionized material (plasma) tends to follow the route delimited by the magnetic lines. On the contrary, when the magnetic steering element is of the steered arc technology type, in which the arc follows the path in which the perpendicular magnetic field is nil, the ionized material must traverse the magnetic flux lines formed by the magnetic steering element before reaching the parts to be coated, which can have negative effects on the kinetic energy of the deposited material and, therefore, on the quality of the coating obtained.

The drawback of “perpendicular” magnetic steering elements with respect to the steering elements used in the steered arc technology is that they do not provide a homogeneous use of the evaporation target when the latter exceeds a certain size, therefore “perpendicular” magnetic steering elements are more suitable for small-sized evaporators, which on the other hand facilitates the use of high intensities of the magnetic field, with beneficial effects on the quality of the coating. In contrast, small evaporators develop a higher density of energy per unit area of evaporation target, which contributes to increasing the proportion of microdroplets in the coating.

JP-A-2-194167 describes a system with a type of magnetic steering element which is relatively powerful, in which there is a constriction of the magnetic field in the space present between the evaporation target and the substrate to be coated. The described system supposedly achieved a considerable reduction in the amount of microdroplets emitted by the arc evaporator.

JP-A-4-236770 describes a variant of this system in which a small mobile magnet located in the rear part of the evaporation target is added to the constriction coil, the function of which magnet is to prevent an excessive wear in the center of the evaporation target.

EP-A-0495447 (corresponding to JP-A-4-236770) describes a system with a magnetic steering element very similar to the one described above, with the difference that a small mobile magnet, placed in the rear part of the target, is added to it to balance out the wear of the evaporation target in its entire surface.

U.S. Pat. No. 6,139,964 includes a detailed description of an example of a system of this type and of the benefits that it supposedly entails, which include a considerably greater ionization than the one achieved with more conventional arc evaporation methods, especially in terms of the ionization of the gases present in the chamber. As a consequence of this increased ionization of the gaseous species, in the case of the most usual coating process of evaporation of titanium in a nitrogen atmosphere, there is a reaction in the evaporation target between both elements which leads to the formation of a layer of titanium nitride in the surface of the titanium target. Given that this compound (TiN) is much more refractory than the original metal (titanium), one of the consequences of this surface reaction is the considerable reduction in the emission of microdroplets.

Another advantage of the increased ionization is the increase of the stability of the arc, which can be maintained without interruptions at lower electric intensity values, which are also more suitable for reducing the amount of microdroplets in the coating.

Yet another advantage of this type of evaporator is that the temperature of the electrons in the plasma generated in the arc evaporator increases considerably with this type of magnetic field, which makes it easier to obtain top quality coatings.

JP-A-11-269634 describes another variant of a system of this type, in which the constriction of the magnetic field is achieved not with the use of a coil intercalated between the evaporator and the substrate, but by means of the insertion of permanent magnets in the periphery of the evaporation target, although such magnets, unlike the coil described in JP-A-2-194167, are located in the rear part of the target. The idea described in JP-A-2-194167 involved the use of a coil of tens of kilos, located between the evaporator and the chamber, which makes it difficult to access the evaporator for maintenance tasks and the like. The system described in JP-A-11-269634, in addition to simplifying the access to the evaporator and its manufacture, also has the merit of eliminating an element (the tube supporting the coil) necessarily located between the evaporator and the substrate in the case of JP-A-2-194167, whereby there is the always interesting possibility of locating the evaporator closed to the coating substrate, which usually translates into a better quality coating, although it also involves a more focused distribution of the evaporated material.

To reduce the problem associated with the greater wear occurring in the center of the target in evaporators of this type with a converging magnetic field, JP-A-11-269634 considers the possibility of modifying the distance between the ring of magnets and the target of the evaporator throughout the life of the evaporation target, such that the intensity of the magnetic field at the edge of the target and its inclination with respect to the perpendicular to the evaporation surface are modified, and thus its tendency to concentrate the discharge in the central area is modified. In the computational calculations graphically shown in JP-A-11-269634 it is seen how an increase of the distance can modify the converging nature of the magnetic field and transform it into a diverging magnetic field, making the arc not only be concentrated in the center, but also tend to be concentrated at the edges. Thus, by using different distances between the ring of magnets and the evaporation target throughout the life of the latter, it is possible to modify the wear profile. In any case, to obtain a homogeneous wear of the target, the system described in JP-A-11-269634 requires, for a considerable time of the life of the evaporation target, performing the coating processes by working with a non-converging magnetic field, whereby the benefits provided by this type of evaporator are lost.

JP-A-2000-328236 describes another solution in which the field is generated by small permanent magnets located coplanar with the evaporation target, such that the central section thereof coincides with the evaporation surface. It is thus achieved that the magnetic field is essentially perpendicular to the evaporation target in its surface. To restrict the access of the arc to the peripheral area of the evaporation target, a part made of a ferromagnetic material is located in the proximity of the entire periphery of the target, which part locally modifies the profile of the magnetic field, making it have a converging nature at this point and, therefore, making it tend to divert towards the center of the target any arc discharge which approaches the edge of the evaporation target. Similarly, JP-A-2000-328236 contemplates the possibility of including a small permanent magnet at the central rear part of the target, such that it tends to move the arc away from the geometric center, achieving a more homogeneous wear. In the system described in JP-A-2000-328236 the beneficial effects of the convergence of the magnetic field have been lost to a great extent.

U.S. Pat. No. 6,103,074 describes a system with an arc evaporator forming a magnetic constriction of the flux (convergence) by means of using two coils, one located in front of the evaporation surface and the other located behind it. The advantage of adding this rear coil lies in that it allows modifying the degree of convergence of the magnetic flux, and its location with respect to the evaporation target, such that it is possible to adapt it to the specific demands of each coating process.

JP-A-2000-204466 shows a system in which the magnetic field perpendicular to the evaporation target is obtained by means of a series of magnets placed substantially coplanar to the evaporation target, and contemplates the possibility of slightly moving the magnets in a direction perpendicular to the evaporation target to modify the path of the arc on the surface of the evaporation target.

JP-A-2001-040467 describes a system which includes a ring of peripheral magnets inside the structure which acts as the anode of the electric arc discharge. The magnets are thus cooled directly by water and there is no risk of them losing their characteristics due to the effect of the high temperatures (500° C.) to which the inside of the chamber must be subjected to obtain high quality coatings for cutting tools.

JP-A-2001-295030 describes a system similar to the one described in U.S. Pat. No. 6,103,074 in that it is based on using two coils, one placed in front of the evaporation surface and the other one placed behind it, to control the converging or diverging nature of the magnetic flux. The location of the coils makes it necessary to use a specific cooling with water in order to prevent the overheating of the coils, similar to the one shown in U.S. Pat. No. 6,139,964.

JP-A-2003-342717 shows a magnetic configuration formed by no less than three coils for each evaporator. A coil coplanar to the evaporation target creates a magnetic field substantially perpendicular thereto. Another coil creates a magnetic constriction located between the evaporation target and the part to be coated. A third coil, located behind the target, contributes to performing a better wear thereof. However, the use of three coils for each evaporator (12 of which may be typically present in each coating machine) can be expensive and not very practical.

### DESCRIPTION OF THE INVENTION

A first aspect of the invention relates to an arc evaporator, comprising:

at least one anode configured to be located in an evaporation chamber configured to house at least one object to be coated;

a cathode, the cathode comprising
an inner surface configured to be located inside such evaporation chamber such that an arc between said at least one anode and the cathode can cause an evaporation of material in said inner surface, and
an outer surface configured to not be located inside the evaporation chamber; and

a system for generating a magnetic field configured to generate a magnetic field in the evaporation chamber.

According to the invention, the system for generating a magnetic field comprises:
a first subsystem consisting of a set of permanent magnets (the set of permanent magnets consists of one or more permanent magnets) configured to be located outside the evaporation chamber and such that said set of permanent magnets produces a first magnetic field component in correspondence with the inner surface of the cathode, said first magnetic field component being a converging magnetic field component (such that the magnetic field lines at the edge of the cathode tend to converge at a point located in front of the cathode), and
a second subsystem comprising at least one coil configured to be located outside the evaporation chamber and behind the outer surface of the cathode (i.e., in a plane which does not pass through the cathode and which is farther from the inner surface of the cathode than from the outer surface of the cathode), said second subsystem being configured to operate in at least a first operating mode in which it generates a second magnetic field component in said evaporation chamber, said second magnetic field component being a diverging magnetic field component.

The first subsystem creates a converging magnetic field (or magnetic field component) which can have a considerable degree of convergence, with the benefits that this involves in terms of degree of ionization and temperature of the plasma, as has been described above. However, if the total magnetic field had only been formed by this component generated by the first subsystem, there would be a situation of preferential wear of the evaporation target (the cathode) in its central area. The activation of the second subsystem, based on the coil, allows decreasing the degree of convergence of the magnetic field in a controlled manner (by simply varying the current intensity passing through the coil) and adjusting, by means of generating a diverging magnetic field component in the inner surface of the cathode, the “degree of convergence” of the total magnetic field (i.e., of the magnetic field resulting from the sum of the two components) to the precise needs of each stage of the coating process. It is thus possible, for example (not excluding other possibilities), to use a high degree of convergence in the initial stages of the coating, which are very critical, and then gradually decrease that convergence as the coating process progresses in order to obtain a better exploitation of the evaporation target in phases of the coating process which do not require such a high plasma quality.

In other words, the arc evaporator uses a magnetic steering element with a magnetic field of a perpendicular type which establishes a magnetic field with magnetic lines substantially perpendicular to the evaporation surface but which are converging. The degree of convergence can be modified by means of the coil to assure that the wear of the evaporation target occurs in a suitable manner. The structure of the invention allows achieving it with a reduced number of elements, which contributes to making the solution more cost-effective. Furthermore, the elements have a small volume and are located in the suitable location in order to not hinder the access to the evaporator and to the evaporation target for the performance of maintenance tasks. Furthermore, due to its design, the described solution does not require cooling with water which contributes to complicating the manufacture of the evaporator. Additionally, it is possible to make the steering element operate in a “perpendicular” (but “converging”) mode or in a “steered arc” mode, it being possible to even perform this alternation of arc steering modes at frequencies of tens of Hz.

Each permanent magnet of the set of permanent magnets can be a magnet with a magnetization substantially perpendicular to the inner surface of the cathode and of the same direction.

At least some of the magnets of the set of permanent magnets can be housed in a ring with a diameter larger than that of the evaporation target.

Each permanent magnet of the set of permanent magnets can be a magnet with a magnetization substantially perpendicular to the inner surface of the material to be evaporated and of the same direction, such that the perpendicular component of said first magnetic field component has the same direction in the entire inner surface of the cathode.

Each permanent magnet of the set of permanent magnets can be a magnet with a magnetization substantially perpendicular to the inner surface of the material to be evaporated and of the same direction, the perpendicular component of said first magnetic field component having the same direction in the entire inner surface of the cathode except in the center of its surface, in which the magnetic field has a direction reverse to that of the edges but with an intensity less than 10 gauss (10 gauss is the total intensity, i.e., the sum of the fields generated by all the magnets).

The magnetic field generated by the coil can be substantially perpendicular to the surface of the cathode in its entire surface, such that there are no points at which the magnetic field is parallel to the surface of the cathode.

The evaporator can be configured such that the magnetic field generated by the coil can be modified by varying the electric current circulating therethrough such that the overall magnetic field, created by the coil and the permanent magnets, can become converging, diverging or forming a path of points with nil perpendicular magnetic field on the inner surface of the material to be evaporated, by simply varying the electric current circulating through the coil.

The set of permanent magnets of the first subsystem can be located behind the outer surface of the cathode.

The set of permanent magnets of the first subsystem can be arranged in the form of at least one ring concentric with the cathode. For example, said set of permanent magnets of the first subsystem can be arranged in the form of at least two rings concentric with the cathode.

The permanent magnets of said set of permanent magnets can be manufactured from ferrite, neodymium-iron-boron or cobalt-samarium.

The permanent magnets can be arranged with their respective magnetic orientations arranged with cylindrical symmetry about the axis of symmetry of the cathode.

The magnets can be arranged with their respective magnetic orientations parallel and with the same direction.

The magnets can be arranged with their magnetization perpendicular with respect to the inner surface of the cathode.

The set of permanent magnets can comprise an outermost ring of magnets the diameter of which is larger than the diameter of the inner surface of the cathode.

The set of magnets can be located on a casing of the coil.

The coil can be located farther from the cathode than the set of permanent magnets, such that said set of permanent magnets is located between the coil and the cathode according to an axis perpendicular to the cathode.

The coil can be concentric with the cathode.

The coil can be associated with an electric power supply system configured to selectively operate the coil in said first operating mode.

The coil can be associated with an electric power supply system which allows modifying the intensity circulating through the coil, such that by increasing the intensity circulating therethrough it is possible to reduce the converging nature of the magnetic field resulting from the sum of the magnetic field generated by the permanent magnets and the field generated by the coil.

The electric power supply system can be configured to selectively operate the coil in a second operating mode with a current direction through the coil opposite to the current direction in said first operating mode, the second subsystem being configured such that, in said second operating mode, the magnetic field in correspondence with the inner surface of the cathode is parallel to said inner surface along at least one course. The intention is for the coil, together with the permanent magnets, to create a closed magnetic loop of those which are used in steered arc technology. This type of steering can be the most suitable to assure the proper wear of the areas very close to the edge of the evaporation target, therefore they can be used to increase the exploitation of the target even more, at the expense of a lower quality of the bombardment during that phase.

The coil and its power supply can be configured to allow a reversal of the current direction through the coil at a frequency greater than 1 Hz. The direction of the current circulating through the coil during the operation of the evaporator, with a frequency of, for example, several tens of Hz, can thus be reversed. It is thus possible, for example, to alternate two different currents (with a different direction and, optionally, also with a different amplitude) with a frequency of several tens of Hz, and make one of the currents create (together with the permanent magnets) a magnetic field substantially perpendicular to the inner surface of the cathode in correspondence with said surface (although, normally, converging or diverging, especially in the areas of the edges of the inner surface of the cathode), whereas the other current causes a steered arc technology type steering to appear.

The evaporator can comprise a system for cooling the cathode comprising means for carrying a cooling fluid such that it cools the outer surface of the cathode (3). These cooling means also establish a type of shield protecting the subsystems for generating a magnetic field from the heat coming from the evaporation chamber.

The evaporator can further comprise said evaporation chamber, the evaporation chamber being configured to house at least one object to be coated,

said at least one anode being located in said evaporation chamber,

the cathode being located with its inner surface inside the evaporation chamber,

said set of permanent magnets being located outside said evaporation chamber,

and said at least one coil being located outside said evaporation chamber.

Another aspect of the invention relates to a method for operating an evaporator according to the invention, comprising the steps of:

placing at least one object to be coated inside the evaporation chamber,

establishing an arc between said at least one anode and the cathode, to cause evaporation in the inner surface of the cathode; and

controlling the degree of convergence of the magnetic field in correspondence with the inner surface of the cathode by varying the current intensity through said at least one coil.

For example, said current can be varied such that a higher degree of convergence of said magnetic field is used in a first stage and a lower degree of convergence of the magnetic field is used in a subsequent stage of the coating process, in order to obtain a better exploitation of the evaporation target.

### DESCRIPTION OF THE DRAWINGS

To complement the description and for the purpose of aiding to better understand the features of the invention according to preferred practical embodiments thereof, a set of figures is attached as an integral part of said description, in which the following has been depicted with an illustrative and non-limiting character:

FIG. 1 shows a schematic cross-sectional view of the evaporator according to a possible embodiment of the invention. In this case, the converging magnetic field created only by the permanent magnets located behind the evaporation target is depicted.

FIG. 2 shows a schematic cross-sectional view of the evaporator according to a possible embodiment of the invention. In this case, the diverging magnetic field created only by the coil located behind the evaporation target, without the contribution of the permanent magnets, is depicted.

FIG. 3 shows a schematic cross-sectional view of the evaporator according to a possible embodiment of the invention. In this case, the steered arc type magnetic field which can be created with the participation of both systems, for a suitable adjustment of the intensity circulating through the coil, taking into account the intensity of the magnetic field created in turn by the permanent magnets, is depicted.

FIG. 4 is a graphic depiction of the magnetic fields generated by the coil, without permanent magnets, when 2500 amperes-turn circulate therethrough.

FIG. 5 is a graph of the tangential component of the magnetic field in the inner surface of the evaporation target, taking the center thereof as the coordinate system origin, when 2500 amperes-turn circulate through the coil and without taking into account the contribution of the permanent magnets.

FIG. 6 is a graphic depiction of the magnetic fields generated by the set of permanent magnets, without current circulating through the coil.

FIG. 7 is a graph of the tangential component of the magnetic field in the inner surface of the evaporation target, taking the center thereof as the coordinate system origin, generated by the set of permanent magnets, without current circulating through the coil.

FIG. 8 is a graphic depiction of the magnetic fields generated by the set of permanent magnets and the coil, when 1250 amperes-turn circulate therethrough.

FIG. 9 is a graph of the tangential component of the magnetic field in the inner surface of the evaporation target, taking the center thereof as the coordinate system origin, generated by the set of permanent magnets and the coil, when 1250 amperes-turn circulate therethrough.

FIG. 10 is a graphic depiction of the magnetic fields generated by the set of permanent magnets and the coil, when −2500 amperes-turn circulate therethrough.

FIG. 11 is a graph of the normal component of the magnetic field in the inner surface of the evaporation target, taking the center thereof as the coordinate system origin, generated by the set of permanent magnets and the coil, when −2500 amperes-turn circulate therethrough.

FIG. 12 is a graphic depiction of the magnetic fields generated by the second set of permanent magnets, without current circulating through the coil.

FIG. 13 is a graph of the normal component of the magnetic field in the inner surface of the evaporation target, taking the center thereof as the coordinate system origin, generated by the second set of permanent magnets, without current circulating through the coil.

FIG. 14 is a graphic depiction of the magnetic fields generated by the second set of permanent magnets and the coil, when 600 amperes-turn circulate therethrough.

FIG. 15 is a graph of the tangential component of the magnetic field in the inner surface of the evaporation target, taking the center thereof as the coordinate system origin, generated by the second set of permanent magnets and the coil, when 600 amperes-turn circulate therethrough.

FIG. 16 is a graphic depiction of the magnetic fields generated by the second set of permanent magnets and the coil, when 2500 amperes-turn circulate therethrough.

FIG. 17 is a graph of the tangential component of the magnetic field in the inner surface of the evaporation target, taking the center thereof as the coordinate system origin, generated by the second set of permanent magnets and the coil, when 2500 amperes-turn circulate therethrough.

FIG. 18 is a graphic depiction of the magnetic fields generated by the second set of permanent magnets and the coil, when −2500 amperes-turn circulate therethrough.

FIG. 19 is a graph of the normal component of the magnetic field in the inner surface of the evaporation target, taking the center thereof as the coordinate system origin, generated by the second set of permanent magnets and the coil, when −2500 amperes-turn circulate therethrough.

FIG. 20 is a graphic depiction of the magnetic fields generated by a set of permanent magnets placed in a magnetic orientation similar to the used in JP-A-11-269634.

FIGS. 21 and 22 are schematic figures to which references is made in the clarification of the meaning of the term “converging”.

### PREFERRED EMBODIMENTS OF THE INVENTION

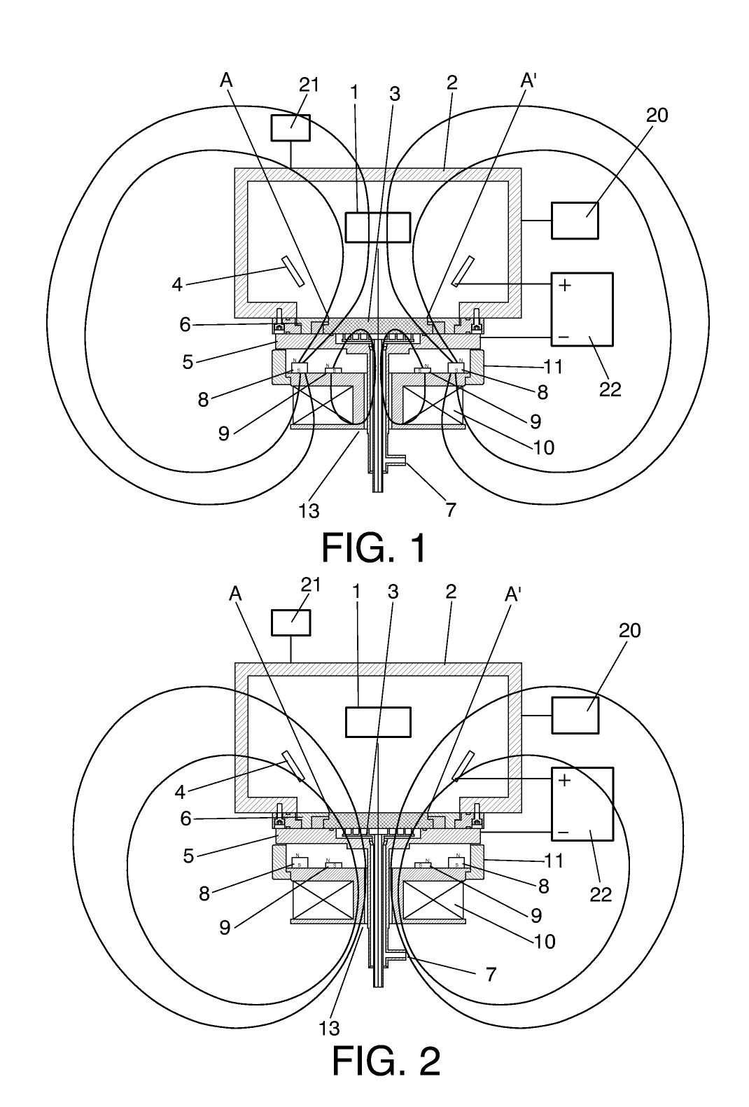

FIGS. 1-3 schematically depict an evaporator according to a preferred embodiment of the invention which comprises an evaporation chamber 2. A part 1 to be coated has been introduced into this chamber 2. Before starting the coating process, a suitable vacuum level (for example, 5×10⁻⁸ bar) is established by means of using vacuum pumps 20. During the vacuum generation cycle, heaters (not depicted) emitting infrared radiation can be turned on to heat the part 1 to be coated to the required temperature. Depending on the type of process, these heaters can be turned on during the entire coating process.

Once the required vacuum level is reached, a certain flow of gas is introduced into the chamber by means of a corresponding gas pump 21, such that the equilibrium pressure between the gas aspirated by the vacuum pumps 20 and the gas which is introduced is around 10⁻⁵ bar. Once this pressure has been reached, the electric discharges in the evaporators can be started, which discharges cause an emission of material by evaporation from the evaporation target (namely, cathode 3), which will move through the partial vacuum to the part to be coated, in which that recently deposited material can in turn react with the gas present in the chamber. In the schematic depiction, the mobile elements which are conventionally used to ignite an arc discharge of this type (examples of mobile elements of this type are described in some of the documents mentioned and discussed above) have been excluded for the sake of simplicity.

The electric arc discharge is maintained as a result of the action of an electric source 22 especially designed for the task, which is in charge of preventing the discharge from spontaneously self-extinguishing. The discharge occurs between the evaporation target 3 and suitably cooled elements acting as the electric discharge anode 4. The evaporation target 3 or cathode is secured to a body 5 in which there is housed a series of elements necessary for cooling the rear part of the evaporation target with water, as well as for the vacuum sealing against the body of the chamber 2, as is conventional in systems of this type. In the example illustrated in FIGS. 1-3, the cooling water enters and exits the body 5 through an axial prolongation 7 running through the central area of the magnetic field generating elements which are described below and which are designed such that they allow easily disassembling the magnetic components.

To perform a suitable electric insulation between the evaporation target 3 and the body of the chamber 2, a series of electrically insulating elements 6 compatible with high vacuum and high temperature has been placed, which elements must be subjected to a periodic maintenance to prevent the deterioration of the electric insulation as they are gradually coated with the material evaporated from the evaporation target.

All the elements forming part of the body of the evaporator are manufactured with materials which do not have any degree of ferromagnetism, i.e., their relative magnetic permeability is less than 1.2.

All the elements necessary for generating the magnetic fields necessary for an evaporation target with a diameter of 100 mm and a thickness of 15 mm, as the one shown in the figure, are located at the rear part of the evaporator, i.e., behind the evaporation target 3, according to an axis perpendicular to the evaporation target and according to which the object to be coated 1 is located in front of the evaporation target 3.

A coil 10, capable of being fed at 2500 amperes-turn, has been housed in a body of an insulating material in the form of a reel 13. For a coil suitable for the aforementioned evaporation target with a diameter of 100 mm of diameter, that value of the current is low enough to not require a specific cooling. On the reel 13 there are placed two concentric rings (8, 9) of magnets with a high density of energy, manufactured in neodymium-iron-boron or in cobalt-samarium, for example, with their magnetizations parallel to one another and in a direction perpendicular to the inner surface of the evaporation target (i.e., to the surface located inside the evaporation chamber), and with the same polarization for both rings (i.e., the outer ring 8 and the inner ring 9). The entire assembly is simply secured to the body of the evaporator by means of an accessory part 11.

For example, according to a preferred embodiment, the rings of magnets are manufactured based on cobalt-samarium magnets with a diameter of 16 mm and a height of 5 mm. In the outer ring 8 the magnets are stacked to reach a height of 10 mm, whereas the inner ring 9 has a height of 5 mm. The mean diameters of the rings are 84 in the case of the inner ring 9 and 146 mm in the case of the outer ring 8, and the distance between the support base of the rings and the inner surface (the evaporation surface inside the chamber 2) of the evaporation target is 52 mm.

FIG. 1 includes a simplified schematic depiction of the magnetic lines corresponding to the magnetic field created by the magnets. This depiction demonstrates that this is a confluent or converging field, i.e., a magnetic field such that the prolongations tangent to the field lines at the edges of the evaporation target, i.e., at points A and A′ of FIG. 1, are at a point which is located in front of the evaporation target. In contrast, a diverging field would be that in which those straight prolongations tangent to the magnetic lines at points A and A′ are at a point located behind the evaporation target.

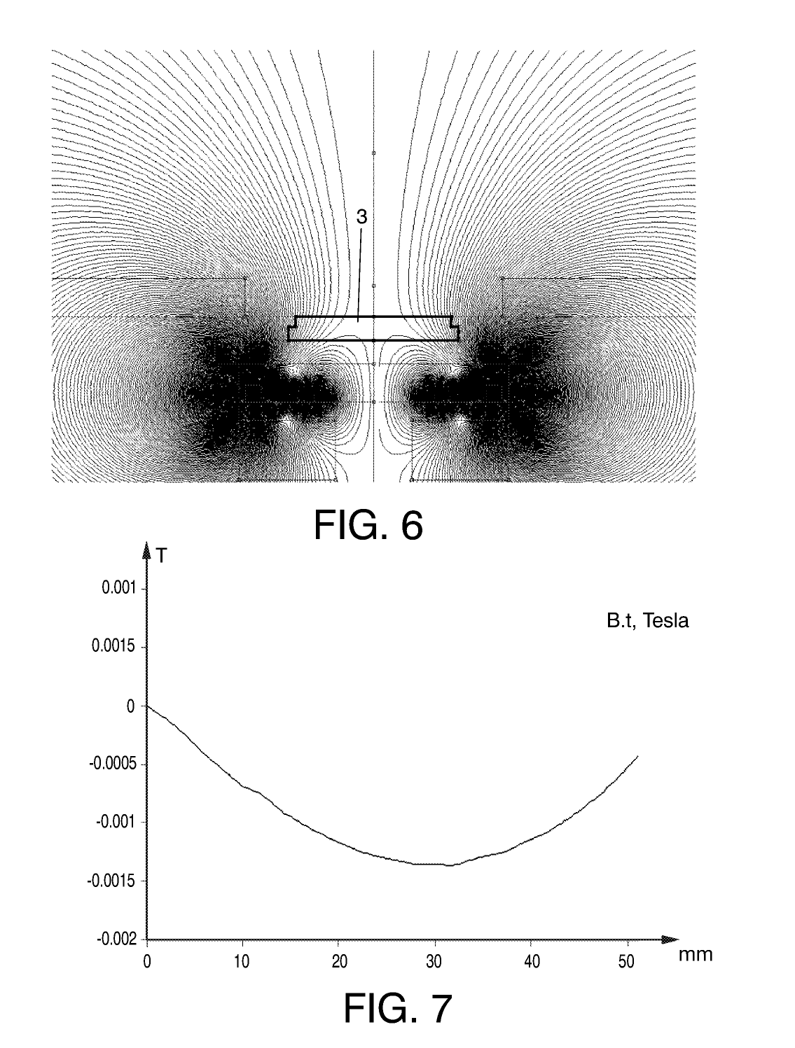

With these features, the magnetic field which is obtained in the absence of current in the coil 10 is illustrated in more detail in FIG. 6. FIG. 7 shows the graphic depiction of the component of the magnetic field (in tesla (T)) parallel to the evaporation surface in correspondence with said surface, from the center of the evaporation target 3, which is taken as the coordinate system origin, to its periphery, at a distance of 50 mm from the center. The component is cancelled out in the center, as is logical due to symmetry, and then is negative in the entire width of the target, which corresponds to a converging magnetic field in the entire surface of the target, as shown in FIG. 6.

In the graph it can be seen that the tangential component at the edge of the target (i.e., at 50 mm from the center) is in the order of −5 gauss, so this arrangement is slightly converging in the absence of current through the coil.

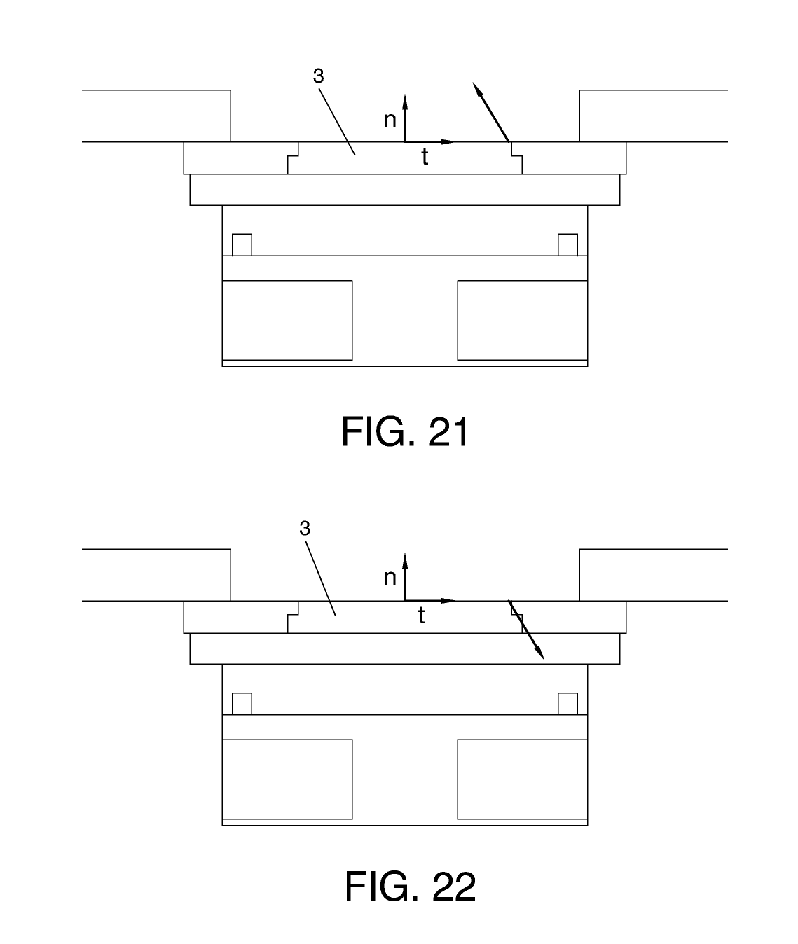

As has been mentioned, it is considered that a converging field is that in which the magnetic field lines tend to be concentrated in front of the inner surface of the material to be evaporated. With the definition of coordinates shown in FIG. 21, which takes as the origin the center of the inner surface of the evaporation material and the vectors t (tangential) and n (normal) as drawn in FIG. 21, it can be seen that a converging magnetic field is characterized by one of the two possibilities set forth in FIGS. 21 and 22, i.e., the magnetic field is converging if the magnetic field at the edge of the evaporation material has a positive perpendicular component (B*n) and a negative parallel component (B*t) (FIG. 21) or inversely, if the magnetic field at the edge of the evaporation surface has a negative perpendicular component (B*n) and a positive parallel or tangential component (B*t) (FIG. 22). For the sake of simplicity, the magnetic orientation of the magnets and the positive direction of the electric current in the coil has been chosen in the mentioned examples such that it generates a perpendicular field of a positive direction in the entire surface of the material to be evaporated, so, with these indicated conventions, a negative tangential component at the edge of the material to be evaporated gives rise to a converging field, whereas a positive tangential component gives rise to a diverging magnetic field.

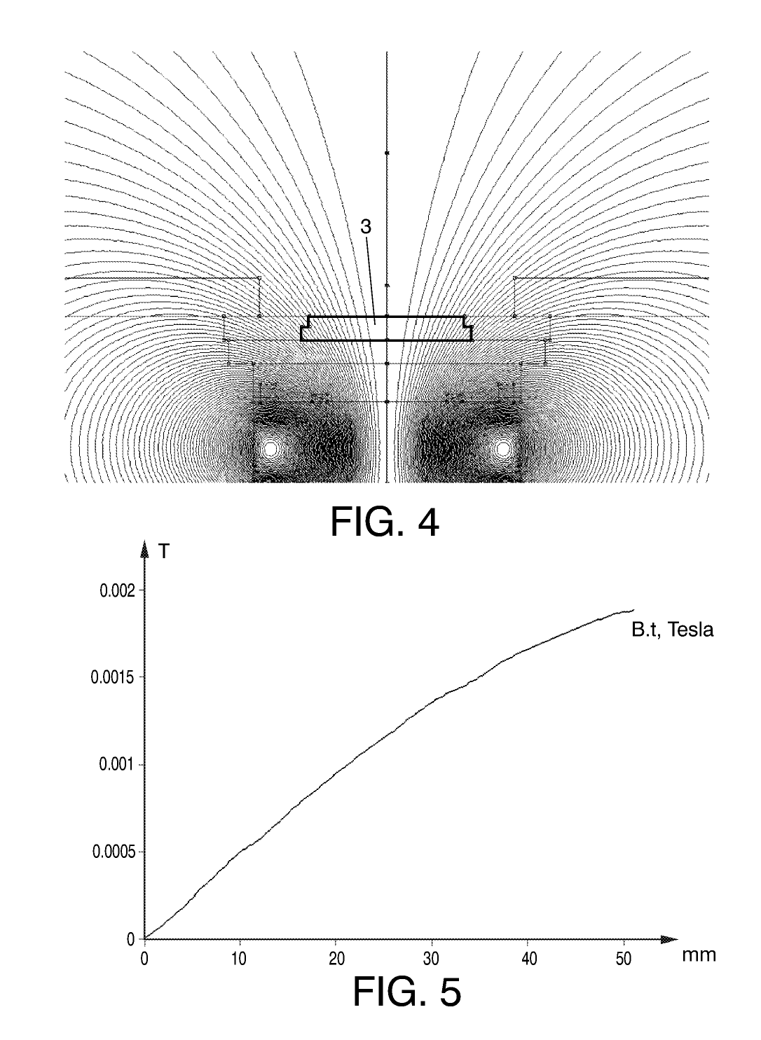

In contrast, the magnetic field generated only by the coil 10, without the presence of permanent magnets, when 2500 amperes-turn circulate through the coil, is the one shown in a simplified manner in FIG. 2 and in a more detailed manner in FIG. 4. As can be seen, this field is diverging. FIG. 5 shows the graphic depiction of the parallel component of the magnetic field (in tesla (T)) in the evaporation surface, from the center of the target to its periphery, at a distance of 50 mm. Once again, the component is cancelled out in the center due to symmetry, and after that it becomes increasingly positive, i.e., increasingly diverging, as shown in FIG. 2. This field depicted herein is never used in practice because the permanent magnets are always present, but these figures serve to illustrate the increase of the diverging nature of the magnetic field when the coil is activated.

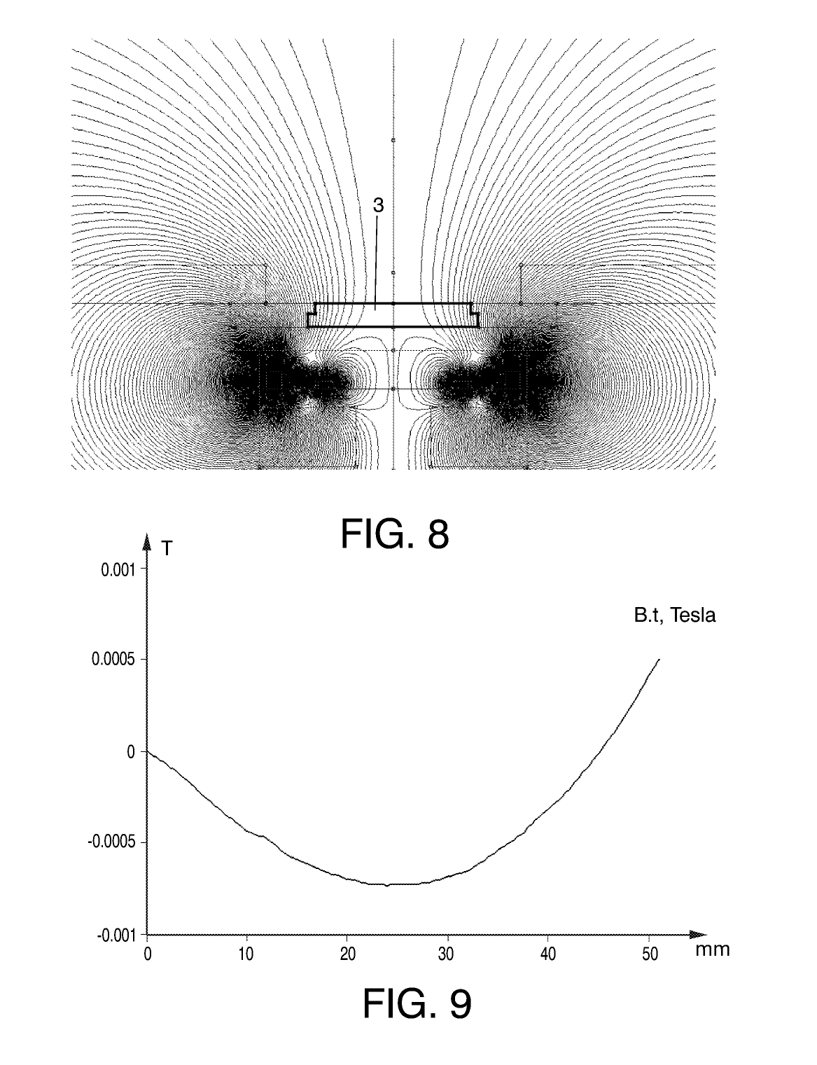

FIG. 8 shows the result of adding the magnetic field generated by the magnets (8, 9) with the one generated by the coil 10, when a current of 1250 amperes-turn circulates therethrough. As can be seen in FIG. 9, with this arrangement of permanent magnets this intensity is enough for the tangential component of the magnetic field to be slightly positive at the edge of the evaporation target, so the magnetic field is slightly diverging. It is therefore clear that by modifying the current circulating through the coil between 0 amperes-turn and 1250 amperes-turn, it is possible to reach the desired degree of divergence or convergence, between the slight convergence of 0 amperes-turn to the slight divergence of 1250 amperes-turn, which allows adjusting the wear profile of the evaporation target and the degree of ionization of the evaporated material.

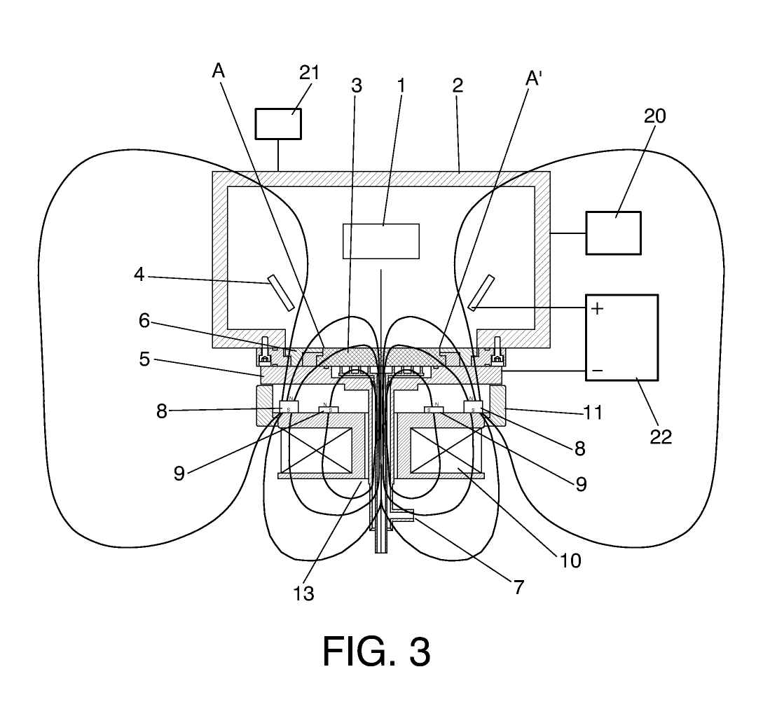

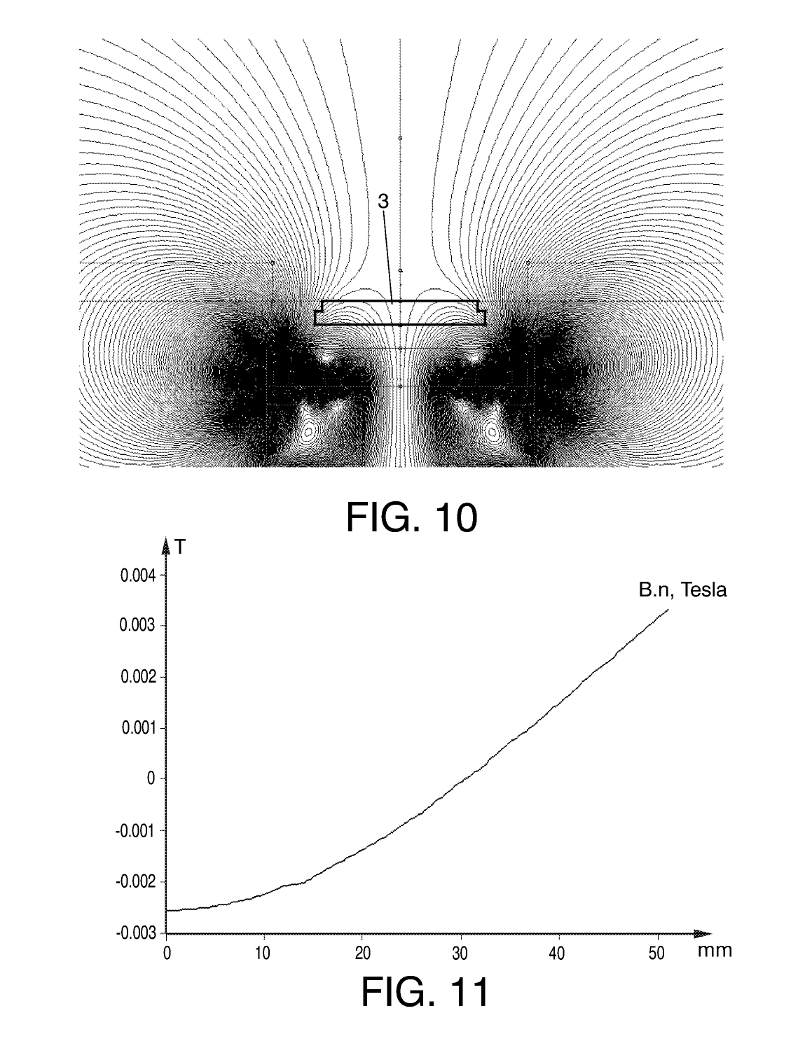

When −2500 amperes-turn are circulated through the coil, the magnetic field shown in a simplified manner in FIG. 3 and in a more detailed manner in FIG. 10 is obtained, which, as can be seen, is a field of the type used in steered arc technology steering elements. FIG. 11 does not depict the tangential component of the magnetic field, since it is positive at all times, but rather it depicts the normal component (in tesla). As can be observed, the normal component is canceled out for a movement from the center close to 30 mm. Therefore, in this case the arc will tend to be trapped in a circular path with a radius of 30 mm.

As a complement, the magnetic fields for a configuration in which the inner ring of magnets 9 of the previous configuration has been dispensed with are analyzed in the following figures.

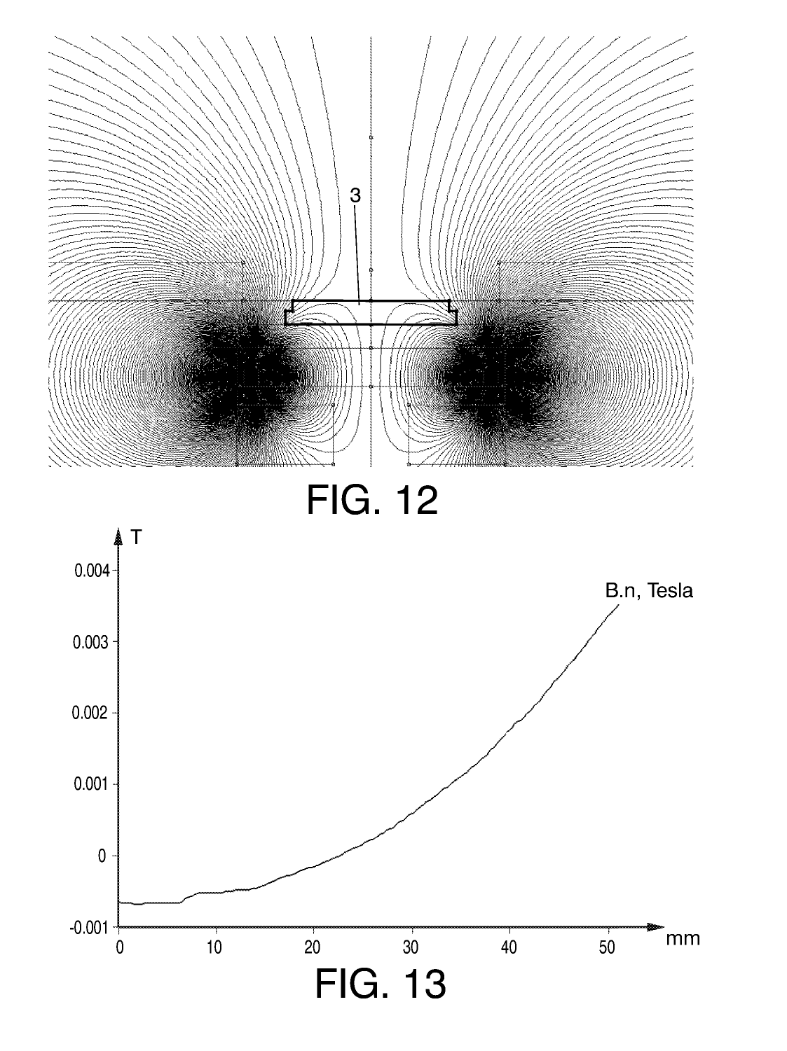

In this case, FIG. 12 depicts the magnetic field in the absence of current in the coil. For this case, the resulting magnetic field is already of the steered arc type, although with a very weak steering, as can be seen in the graph of the normal component (FIG. 13), in which it is observed that this component is canceled out for a radius of about 23 mm, and that the perpendicular component in the center of the target is weak, about 6 gauss.

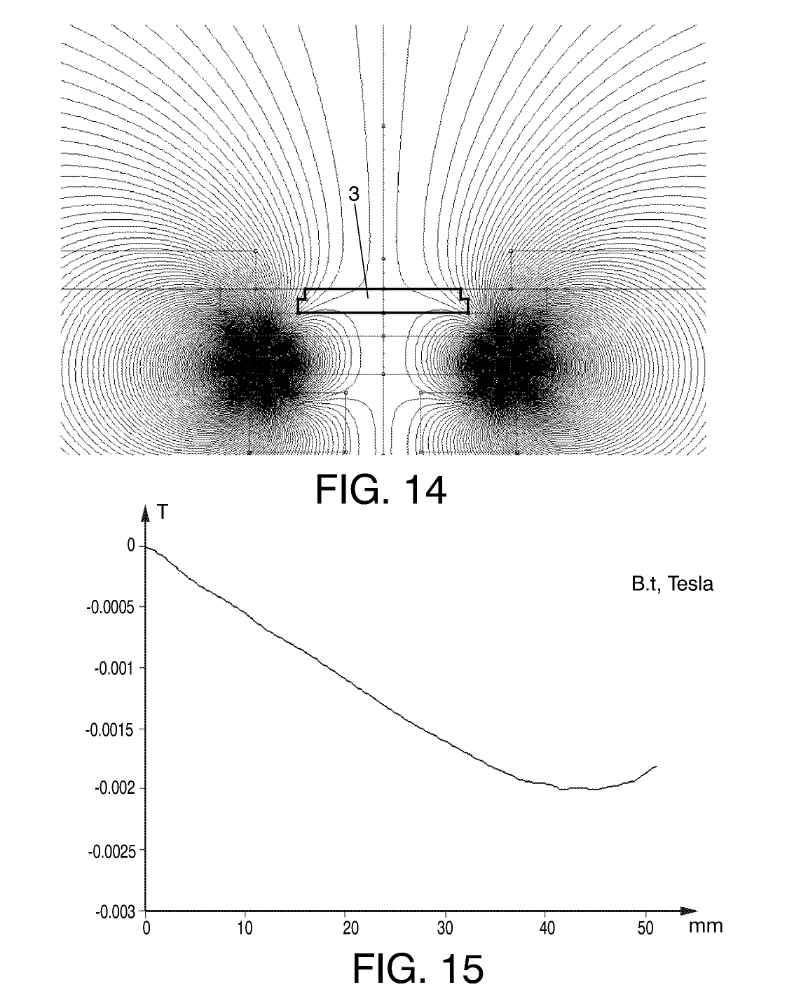

FIG. 14 shows the field for a current through the coil of about 600 amperes-turn. In this case, the field is quite converging, as can be seen in the graph of the tangential component (FIG. 15), in which it is seen that the tangential component of the field at the edge of the evaporation target is about −15 gauss.

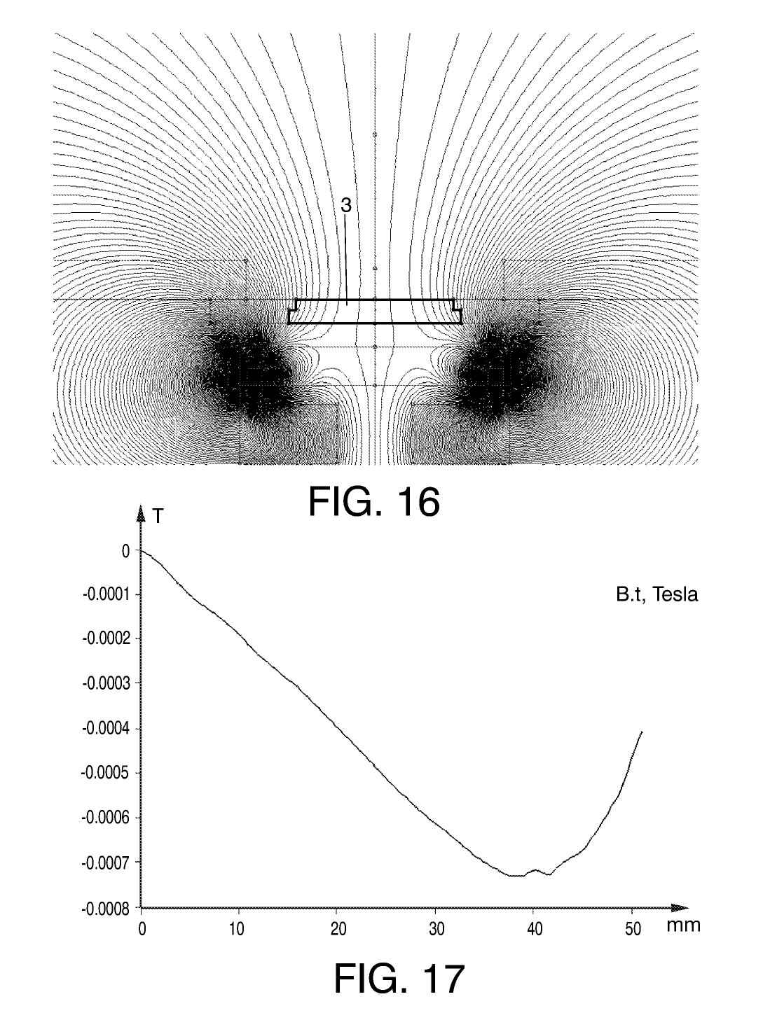

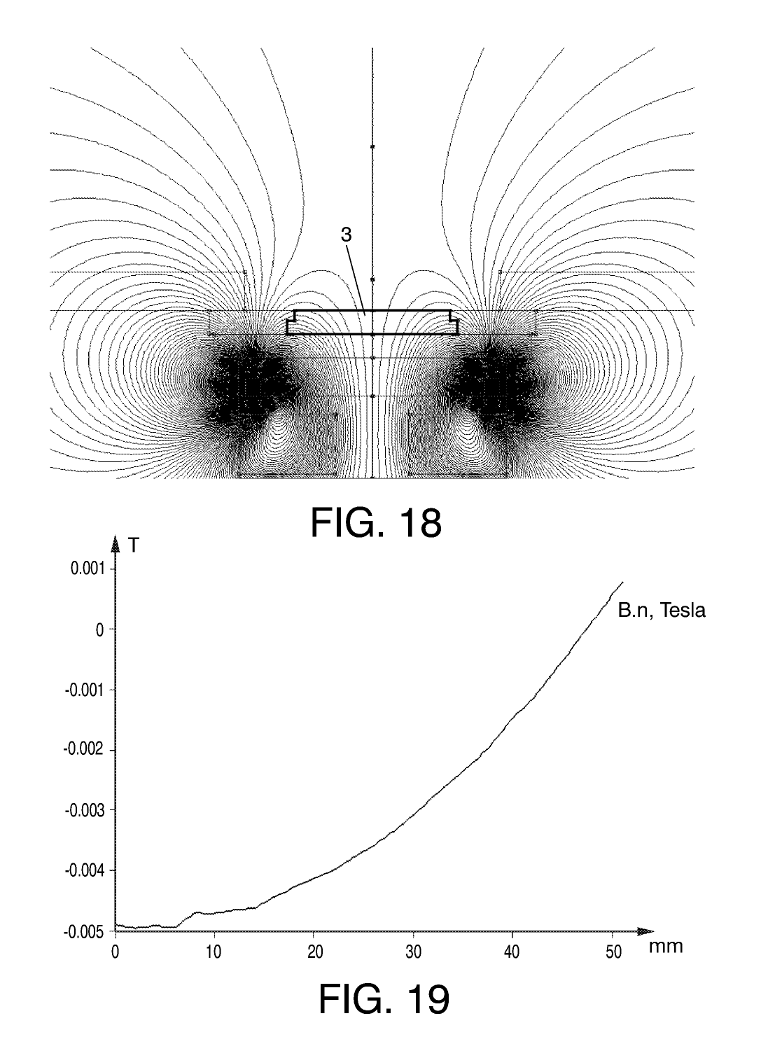

For a current of 2500 amperes-turn, the generated field is the one shown in FIG. 16 which, as can be seen in FIG. 17, reaches a tangential value of the magnetic field at the edge of the target of −4 gauss, so it is still converging, although slightly.

Finally, for a value of current of −2500 amperes-turn, it is seen in FIG. 18 that the generated field is of the steered arc type, and that the radius of gyration of the arc, according to the graph of the normal component of the magnetic field shown in FIG. 19, is about 47 mm, i.e., very close to the edge of the evaporation target.

As can be seen from the analysis of these two slightly different configurations, following the basic principles of the design set forth, it is possible to adjust the sizes of the permanent magnets used such that, by simply modifying the intensity circulating through the coil, a magnetic field which is intensely converging, perpendicular, slightly diverging or even a magnetic field of the steered arc technology type which keeps the arc turning in a circle with a well-defined diameter, controllable from the central area to the periphery itself of the evaporation target, can be obtained.

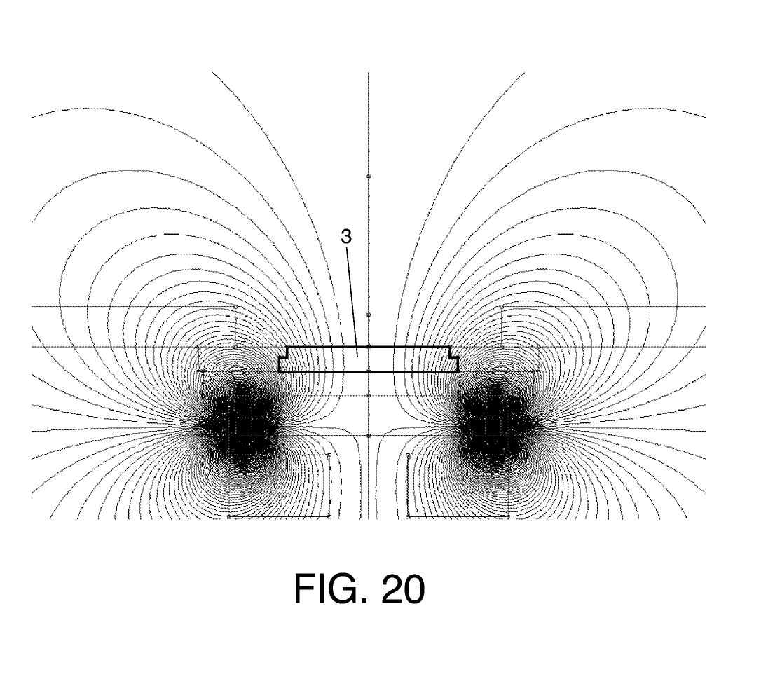

As a comparison, FIG. 20 shows the field obtained when in the last examined configuration of magnets and coil, the orientation of the permanent magnets is modified to orient them in the manner proposed in JP-A-11-269634. In this particular case, it is seen that a converging magnetic field in the surface of the evaporation target is no longer obtained. To achieve it, it would be necessary to further separate the magnets from one another, i.e., increase the size of the ring of magnets, and move them closer to the plane of the evaporation surface, as set forth in said publication. The drawback of all this is that the magnets are very close to the evaporation chamber, or inside it, and it is necessary to take specific measures to prevent the heat coming from the coating process from overheating the magnets, which are frequently very sensitive to the temperature. For example, in JP-A-2001-040467, the magnets are in a location similar to the one described in JP-A-11-269634, but immersed in a water bath. One of the advantages of the arrangement of magnets of the present invention is that, since the magnets are exactly behind the body of the evaporator, it does not require a specific system for cooling, since the cooling itself of the evaporation target prevents the arrival of heat due to infrared radiation from the heaters inside the machine.

Logically, it is possible to combine the described evaporator with other known techniques for increasing the quality of the performance. Such modifications are within the reach of a person skilled in the art, without it being considered that they modify the constitution of the evaporator described herein.

In this text, the word “comprises” and its variants (such as “comprising”, etc.) must not be interpreted in an exclusive manner, i.e., they do not exclude the possibility that what is described includes other elements, steps etc.

On the other hand, the invention is not limited to the specific embodiments which have been described but rather it also covers, for example, the variants which can be made by the person having ordinary skill in the art (for example, in relation to the choice of materials, dimensions, components, configuration, etc.), within what is inferred from the claims.

1. Arc evaporator, comprising:
a) at least one anode (4) configured to be located in an evaporation chamber configured to house at least one object to be coated;
b) a cathode (3), the cathode comprising
an inner surface configured to be located inside the evaporation chamber such that an arc between said at least one anode (4) and the cathode (3) can cause an evaporation of material in said inner surface, and
an outer surface configured to not be located inside the evaporation chamber; and
c) a system for generating a magnetic field configured to generate a magnetic field in the evaporation chamber,
characterized in that said system for generating a magnetic field comprises
c1) a first subsystem consisting of a set of permanent magnets (8, 9) configured to be located outside the evaporation chamber and such that said set of permanent magnets produces a first magnetic field component in correspondence with the inner surface of the cathode (3), said first magnetic field component being a converging magnetic field component such that the magnetic field lines at an edge of the cathode tend to converge at a point located in front of the cathode, said first magnetic field component being substantially perpendicular to the inner surface of the cathode (3), and
c2) a second subsystem comprising at least one coil (10) configured to be located outside the evaporation chamber and behind the outer surface of the cathode (3), said second subsystem being configured to operate in at least a first operating mode in which it generates a second magnetic field component in said evaporation chamber, said second magnetic field component being a diverging magnetic field component.

2. Arc evaporator according to claim 1, wherein each permanent magnet of the set of permanent magnets is a magnet with a magnetization substantially perpendicular to the inner surface of the cathode and of the same direction.

3. Arc evaporator according to claim 1, wherein at least some of the magnets of the set of permanent magnets are housed in a ring with a diameter larger than that of the evaporation target.

4. Arc evaporator according to claim 1, wherein each permanent magnet of the set of permanent magnets is a magnet with a magnetization substantially perpendicular to the inner surface of the cathode and of the same direction, such that the perpendicular component of said first magnetic field component has the same direction in the entire inner surface of the cathode.

5. Arc evaporator according to claim 1, wherein each permanent magnet of the set of permanent magnets is a magnet with a magnetization substantially perpendicular to the inner surface of the material to be evaporated and of the same direction, the perpendicular component of said first magnetic field component having the same direction in the entire inner surface of the cathode except in the center of its surface, in which the magnetic field has a direction reverse to that of the edges but with an intensity less than 10 gauss.

6. Evaporator according to claim 1, characterized in that the magnetic field generated by the coil is substantially perpendicular to the inner surface of the cathode in its entire surface, there being no points at which the magnetic field is parallel to the surface of the cathode.

7. Evaporator according to claim 1, characterized in that it is configured such that the magnetic field generated by the coil can be modified by varying the circulating electric current such that the overall magnetic field created by the coil and the permanent magnets can become converging, diverging or forming a path of points with a nil perpendicular magnetic field on the inner surface of the material to be evaporated, by simply varying the electric current circulating through the coil.

8. Evaporator according to claim 1, characterized in that the set of permanent magnets of the first subsystem is located behind the outer surface of the cathode (3).

9. Evaporator according to claim 1, characterized in that the set of permanent magnets of the first subsystem is arranged in the form of at least one ring (8, 9) concentric with the cathode.

10. Evaporator according to claim 9, characterized in that said set of permanent magnets of the first subsystem is arranged in the form of at least two rings (8, 9) concentric with the cathode.

11. Evaporator according to claim 1, characterized in that the permanent magnets of said set of permanent magnets are manufactured from ferrite, neodymium-iron-boron or cobalt-samarium.

12. Evaporator according to claim 1, characterized in that said permanent magnets are arranged with their respective magnetic orientations arranged with cylindrical symmetry about the axis of symmetry of the cathode.

13. Evaporator according to claim 1, characterized in that the magnets are arranged with their respective magnetic orientations parallel and with the same direction.

14. Evaporator according to claim 1, characterized in that the magnets are arranged with their magnetization perpendicular with respect to the inner surface of the cathode (3).

15. Evaporator according to claim 1, characterized in that said set of permanent magnets comprises an outermost ring of magnets the diameter of which is larger than the diameter of the inner surface of the cathode.

16. Evaporator according to claim 1, characterized in that said set of magnets is located on a casing (13) of the coil (10).

17. Evaporator according to claim 1, characterized in that the coil (10) is located farther from the cathode (3) than the set of permanent magnets (8, 9), such that said set of permanent magnets is located between the coil and the cathode according to an axis perpendicular to the cathode.

18. Evaporator according to claim 1, characterized in that said coil (10) is concentric with the cathode (3).

19. Evaporator according to claim 1, characterized in that the coil is associated with an electric power supply system configured to selectively operate the coil (10) in said first operating mode.

20. Evaporator according to claim 1, characterized in that the coil is associated with an electric power supply system which allows modifying the intensity circulating through the coil, such that by increasing the intensity circulating therethrough it is possible to reduce the converging nature of the magnetic field resulting from the sum of the magnetic field generated by the set of permanent magnets and the magnetic field generated by the coil.

21. Evaporator according to claim 19, characterized in that said electric power supply system is configured to selectively operate the coil (10) in a second operating mode with a current direction through the coil opposite to the current direction in said first operating mode, the second subsystem being configured such that, in said second operating mode, the magnetic field in correspondence with the inner surface of the cathode is parallel to said inner surface along at least one course.

22. Evaporator according to claim 21, characterized in that the coil and its power supply are configured to allow a reversal of the current direction through the coil at a frequency greater than 1 Hz.

23. Evaporator according to claim 1, characterized in that it comprises a system for cooling the cathode comprising means (7) for carrying a cooling fluid such that it cools the outer surface of the cathode (3).

24. Evaporator according to claim 1, characterized in that it further comprises said evaporation chamber, the evaporation chamber being configured to house at least one object (1) to be coated,
said at least one anode being located in said evaporation chamber,
the cathode being located with its inner surface inside the evaporation chamber,
said set of permanent magnets being located outside said evaporation chamber,
and said at least one coil being located outside said evaporation chamber.

25. Method for operating an evaporator according to claim 24, comprising the steps of:
placing at least one object (1) to be coated inside the evaporation chamber,
establishing an arc between said at least one anode and the cathode, to cause evaporation in the inner surface of the cathode; and
controlling the degree of convergence of the magnetic field in correspondence with the inner surface of the cathode by varying the current intensity through said at least one coil.

26. Method according to claim 25, characterized in that said current is varied such that a high degree of convergence of said magnetic field is used in a first stage and a lower degree of convergence is used in a subsequent stage of a coating process for coating an object.
